(19) United States
(12) Patent Application Publication
(10) Pub. No.: US 2013/0077269 A1
(43) Pub. Date: Mar. 28, 2013

(54) HOUSING AND ELECTRONIC DEVICE USING SAME

(71) Applicants: PING LI, Shenzhen City (CN); BAO-GANG ZHAO, Shenzhen City (CN); XUE-FENG WAN, Shenzhen City (CN); YUAN-MING WANG, Shenzhen City (CN)

(72) Inventors: PING LI, Shenzhen City (CN); BAO-GANG ZHAO, Shenzhen City (CN); XUE-FENG WAN, Shenzhen City (CN); YUAN-MING WANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/517,691

(22) Filed: Jun. 14, 2012

(30) Foreign Application Priority Data
Sep. 23, 2011 (CN) 201120360050.2

(51) Int. Cl. H05K 7/00

(52) U.S. Cl. 361/752

(57) ABSTRACT

An electronic device includes a housing, a circuit board fixed to the housing, a connector fixed to the circuit board, and a resisting plate secured to the housing. The resisting plate abuts the circuit board for supporting the circuit board and preventing the connector from loosening.

### BACKGROUND

1. Technical Field

The present disclosure relates to an electronic device; and particularly, to an electronic device having a housing for mounting a connector.

2. Description of Related Art

Electronic devices, such as DVD players, may have at least one connector connected to a circuit board for electrically connecting with an external device for data transmission. However, over time with repeated use, the connector and/or the circuit board may loosen and the electrical connectivity becomes unreliable.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of an embodiment of an electronic apparatus having an electronic device.

FIG. 2 is a partially exploded view of the electronic device of FIG. 1.

FIG. 3 is a partially exploded view of the electronic device of FIG. 1.

FIG. 4 is a partially enlarged view of the electronic device of FIG. 2.

### DETAILED DESCRIPTION

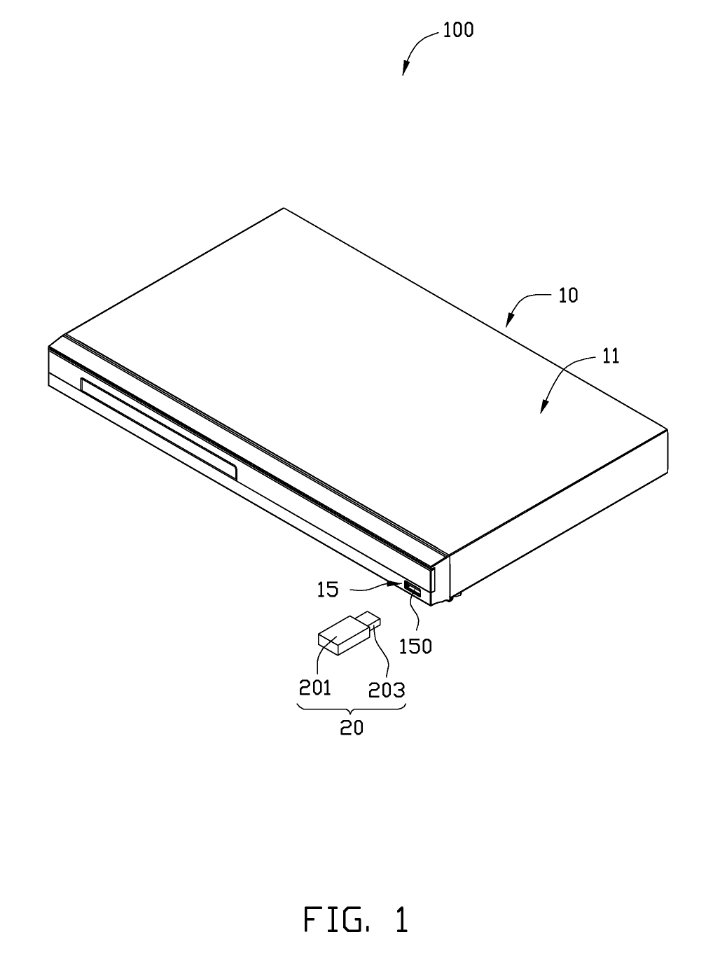

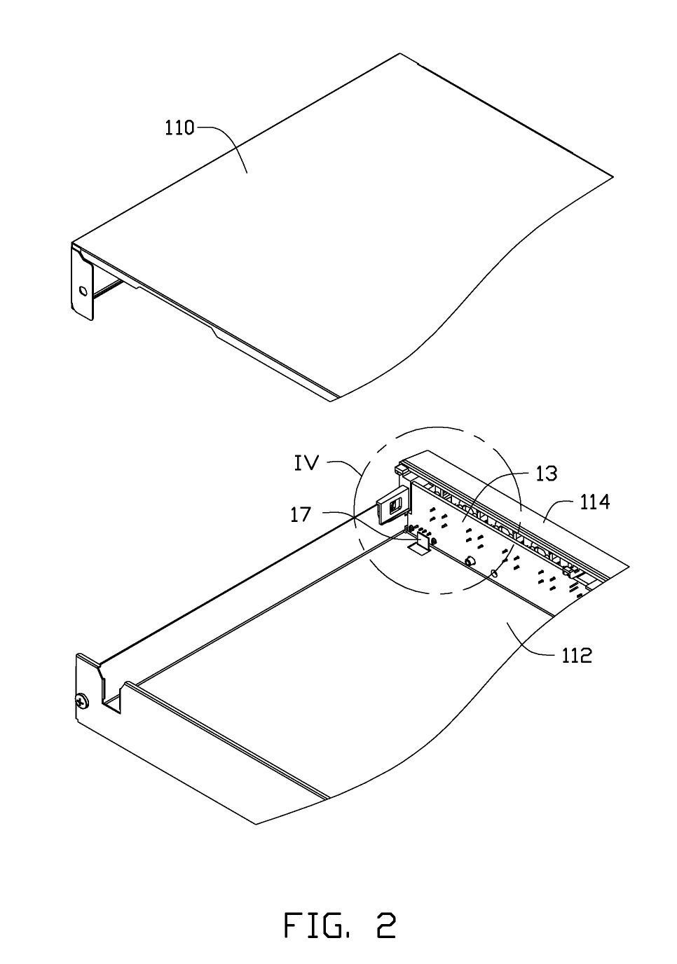

Referring to FIGS. 1 and 2, an electronic apparatus 100 includes an electronic device 10 and an electronic component 20 electrically connected to the electronic device 10. The electronic device 10 has at least one connector 15 for allowing the electronic components 20 to be electrically connected to the electronic device 10. The electronic device 10 may be a DVD player, a computer, or other electronic device. In the illustrated embodiment, the electronic device 10 is a DVD player. The electronic component 20 includes a main body 201 and a plug 203 secured to the main body 201. The plug 203 is capable of being inserted into the connector 15 for electrically connecting to the electronic device 10. In the illustrated embodiment, the electronic component 20 is a USB memory device.

The electronic device 10 further includes a housing 11, a circuit board 13 fixed to the housing 11, and a resisting plate 17 secured to the housing 11.

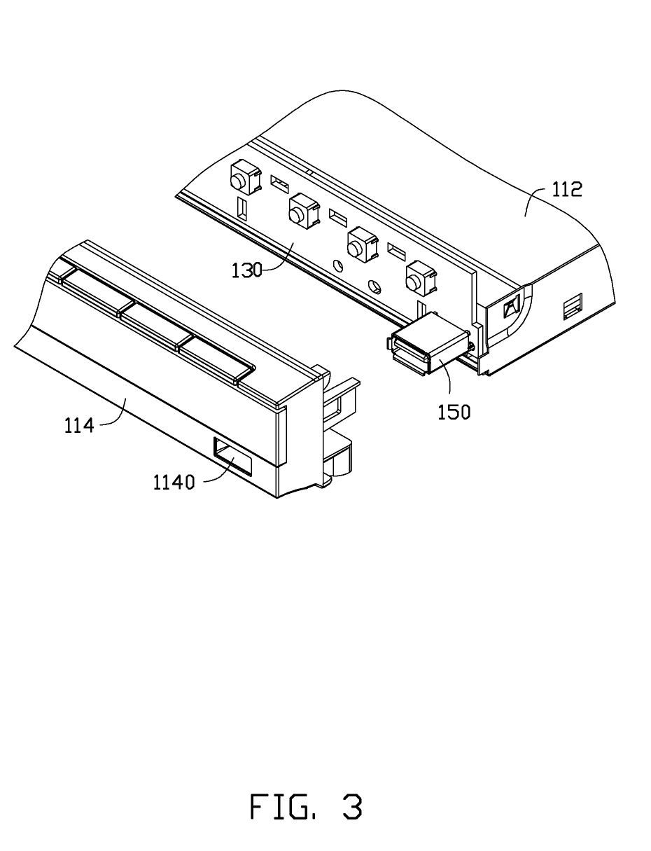

The housing 11 includes an upper cover 110, a lower cover 112, and a plurality of sidewalls connecting the upper cover 110 to the low cover 112. The upper cover 110, the lower cover 112, and the sidewalls cooperatively define an accommodating space (not labeled), for receiving the circuit board 13 and other components (not shown) of the electronic device 10. One of the sidewalls (referred herein as the first sidewall 114) perpendicularly connecting with the lower cover 112 defines a hole 1140 (shown in FIG. 3) for exposing an end of the connector 15 to the outside.

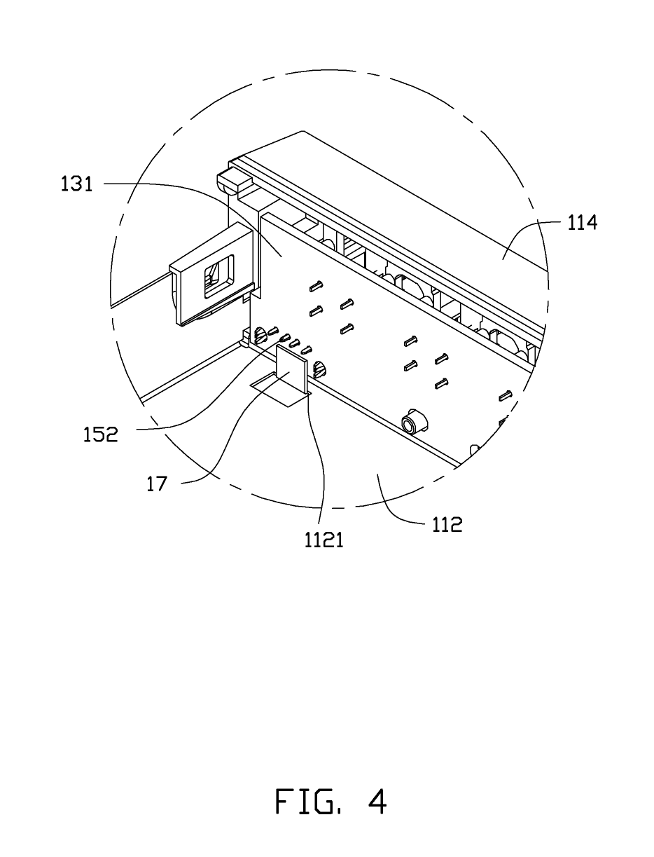

Referring to FIGS. 3 and 4, the connector 15 is mounted to the circuit board 13. The circuit board 13 is fixed to the inner surface of the first sidewall 114, and is substantially parallel to the first sidewall 114. The connector 15 includes a jack 150, and a plurality of terminals 152 protruding from an end of the jack 150. The jack 150 is received in the hole 1140 and is exposed to the first sidewall 114 for contacting with the plug 203 of the electronic component 20. The terminals 152 are secured to and electrically in contact with a first surface 130 of the circuit board 13 facing the sidewall 114.

The resisting plate 17 is formed on the lower cover 112 and is substantially parallel to the first sidewall 114. The resisting plate 17 abuts an area of a second surface 131 of the circuit board 13 opposite to the first surface 130 corresponding to the connector 15. The second surface of the circuit board 13 is covered by an insulation layer except where the resisting plate 17 contacts the circuit board 13, thus, the resisting plate 17 is electrically contacted with the circuit board 13 for conducting static electricity to ground. In the illustrated embodiment, the resisting plate 17 is formed by bending a part of the lower cover 112 toward the circuit board 13.

In assembly, the terminals 152 of the connector 15 are mounted to the first surface of the circuit board 13. The circuit board 13 is secured to the first sidewall 114 with the jack 150 received in the hole 1140. The resisting plate 17 abuts the second surface of the circuit board 13 opposite to the connector 15.

When the plug 203 of the electronic component 20 engages with the jack 150, the resisting plate 17 provides a cushioning force to support the circuit board 13, thus preventing the connector 15 and the circuit board 13 from loosening. Furthermore, the resisting plate 17 electrically contacts the circuit board 13, thus, static electricity of the circuit board 13 is conducted to ground. In addition, the resisting plate 17 is integrally formed on the lower cover 112, thus, improved support for the circuit board 13 and the connector 15 is achieved without the addition of material which is economical.

Although information and the advantages of the present embodiments have been set forth in the foregoing description, together with details of the structures and functions of the present embodiments, the disclosure is illustrative only; changes may be made in detail, especially in the matters of shape, size, and arrangement of parts within the principles of the present embodiments to the full extent indicated by the broad general meaning of the terms in which the appended claims are expressed.

What is claimed is:

1. An electronic device, comprising:
a housing with a resisting plate;
a circuit board fixed to the housing; and
a connector fixed to the circuit board;
wherein the resisting plate abuts the circuit board for supporting the circuit board and preventing the connector from loosening.

2. The electronic device as claimed in claim 1, wherein the resisting plate is formed by bending a part of the housing toward the circuit board.

3. The electronic device as claimed in claim 1, wherein the connector secured to a first surface of the circuit board, the resisting plate abuts a second surface of the circuit board opposite to the first surface to prevent the connector from loosening.

4. The electronic device as claimed in claim 3, wherein the housing comprises a first sidewall and a lower cover perpendicularly connecting with the first sidewall, the circuit board is secured to the first sidewall; the first sidewall defines a hole for exposing the connector.

5. The electronic device as claimed in claim 4, wherein the resisting plate is upwardly formed on the lower cover and abuts an area of a second surface of the circuit board corresponding to the connector.

6. The electronic device as claimed in claim 5, wherein the resisting plate is integrally formed on the lower cover.

7. The electronic device as claimed in claim 1, wherein the resisting plate is a metal sheet and electrically contacts the circuit board for conducting static electricity in the circuit board to ground.

8. A housing of an electronic device, the electronic device comprising a circuit board fixed to the housing and a connector fixed to the circuit board, the housing comprising:
a resisting plate abutting the circuit board for supporting the circuit board and preventing the connector from loosening.

9. The housing as claimed in claim 8, wherein the resisting plate is formed by bending a part of the housing toward the circuit board.

10. The housing as claimed in claim 9, wherein the connector secured to a first surface of the circuit board, the resisting plate abuts a second surface of the circuit board opposite to the first side to prevent the connector from loosening.

11. The housing as claimed in claim 10, wherein the housing comprises a first sidewall and a lower cover perpendicularly connecting with the first sidewall, the circuit board is secured to the first sidewall; the first sidewall defines a hole for exposing the connector.

12. The housing as claimed in claim 11, wherein the resisting plate is upwardly formed on the lower cover and abuts an area of a second surface of the circuit board corresponding to the connector.

13. The housing as claimed in claim 12, wherein the resisting plate is integrally formed on the lower cover.

14. The housing as claimed in claim 8, wherein the resisting plate is a metal sheet and electrically contacts the circuit board for conducting static electricity in the circuit board to ground.
